(19) United States
(12) Patent Application Publication
(10) Pub. No.: US 2016/0333476 A1
(43) Pub. Date: Nov. 17, 2016

(54) Method for producing SOFC cathode diffusion barrier layer and a SOFC

(71) Applicant: Elcogen AS, Tallinn (EE)

(72) Inventors: Enn ÖUNPUU, Tallinn (EE); Juhan SUBBI, Tallinn (EE); Sanni SEPPÄLÄ, Helsinki (FI); Jaakko NIINISTÖ, Vantaa (FI); Markku LESKELÄ, Espoo (FI); Mikko RITALA, Espoo (FI)

(21) Appl. No.: 15/111,200

(22) PCT Filed: Jan. 14, 2014
(86) PCT No.: PCT/EE2014/000001

§ 371 Date: Jul. 13, 2016

(51) Int. Cl. C23C 16/455; H01M 8/1226; C23C 16/40

(52) U.S. Cl. CPC C23C 16/45525; C23C 16/405; C23C 16/45553; H01M 8/1226; H01M 2008/1293

(57) ABSTRACT

The invention provides an improved method for producing cathode diffusion barrier layer, and a SOFC with high efficiency and longevity. It comprises depositing a pure ceria or aliovalently doped ceria layer, by ALD, on the electrolyte layer of the sintered half cell. The surface of a electrolyte onto which film is to be deposited is exposed to a dose of vapor from one or more lanthanide first precursors. Any excess of unreacted vapor from that precursor is removed. Next, a vapor dose of the second precursor is brought to the surface and allowed to react. A second purge completes the ALD cycle, which is repeated to build up thicker films. This ceria layer forms a cathode diffusion barrier layer on top of which a cobaltite based cathode layer is applied by screenprinting, and the cathode diffusion barrier layer and cathode layer are heated together to form a SOFC.

### TECHNICAL FIELD

The invention generally relates to solid oxide fuel cells (SOFC), and more particularly to a method of manufacturing of a cathode diffusion barrier layer and to a cell comprising said barrier layer.

### BACKGROUND OF THE INVENTION

SOFC are one of the possible power sources of the future for the distributed cogeneration of electricity and heat. For this goal to materialize, the working temperature range of SOFC has to be brought down to 600-700° C., from 800-1000° C. to facilitate the use of cheaper construction materials and diminish thermal aging of the systems. This puts special emphasis on one hand to development of solid electrolytes with lower resistivity at these temperatures, and on the other hand, development of new mixed conducting, more efficient, and selectively catalytic electrodes for oxidizing different fuels on anode and reducing oxygen on cathode of the cell. Strontium doped lanthanum cobaltite and ferrite have emerged as potential new cathode materials with higher efficiency at lower temperatures.

These more efficient cobaltite and ferrite cathode materials, however, tend to react with zirconia based electrolytes, and develop layers of high resistivity for ions, lowering SOFC efficiency and longevity. To avoid these undesirable reactions, doped ceria diffusion barrier layers are generally deposited, as ceria is chemically more inert and does not form undesirable compounds with cathode materials under the conditions, where SOFC are produced or used. Ceria, however, forms solid solutions with zirconia that have lower ion conductivity than doped zirconia or ceria. This solid solution formation is significant at temperatures 1300° C. and higher, where cell cofiring provides dense electrolyte layers.

This diffusion barrier layer has to resist diffusion of elements from cathode, preferably strontium and lanthanum, to doped zirconia electrolyte layer in course of the cathode production cycle, and in course of the element full life cycle. The diffusion barrier layer has not to be necessarily dense, but dense layer has significant advantages. The metal atom diffusion on surfaces and grain boundaries is faster than the diffusion through the grain, and so may limit the lifetime of the cell, if the diffusion barrier layer is porous. More, the dense layer will have better contact with the electrolyte for ion transfer.

The doped ceria diffusion barrier layers can been produced by
(i) Screen printing on prefired substrates, followed by sintering between 1200° C. and 1400 C, producing porous layers with thickness 0.5-5 micrometers with some reaction to the substrate [A. Mai et al., Solid State Ionics Vol. 176 (2005) pp 1341-1350];
(ii) Pulsed laser deposition at 400-800° C. producing columnar structure [Jong Hoon Joo, Gyeong Man Choi, Journal of the European Ceramic Society Vol.27 (2007) pp 4273-4277][ K. Rodrigo et al., Appl Phys A Vol. 101 (2010) pp 601-607];
(iii) Physical vapor deposition by magnetron sputtering at 800° C., producing columnar structure, and providing advantages over (i) [N. Jordan et al., Solid State Ionics 179 (2008) pp 919-923].

(ii) and (iii) are conducted at lower temperature and avoid undesirable reactions with electrolyte, however, they still produce porous layers, are expensive technologies, and are hard to expand to large area production.

(i) and (iii) form the closest prior art to present invention.

To overcome these problems in the art, an inexpensive method, namely Atomic Layer Deposition (ALD), of producing dense cathode diffusion barrier layer, appropriate for large area production, and a solid oxide fuel cell with increased efficiency and longevity is described in this invention.

Atomic Layer Deposition is known art [M. Putkonen et al., Chem. Mater. Vol.13 (2001) pp 4701-4707] and used for production of ion conductor layers on porous substrates [International patent application WO02053798, Cassir M. et al, 2002]. The ALD process deposits thin layers of solid materials using two or more different vapor phase precursors. The surface of a substrate onto which film is to be deposited is exposed to a dose of vapor from one precursor. Then any excess unreacted vapor from that precursor is pumped or purged away. Next, a vapor dose of the second precursor is brought to the surface and allowed to react. A second purge completes the ALD cycle. This cycle of steps can be repeated to build up thicker films as described in Paiväsaari, J., Putkonen, M. and Niinistö, L. J. Mater. Chem. Vol.12 (2002) pp 1828-1832, Niinisto, J., Petrova, N., Putkonen, M., Sajavaara, T., Arstila, K. and Niinistö, L. J. Cryst. Growth Vol.285 (2005) pp 191-200. and Putkonen, M., Nieminen, M., Niinistö, J., Sajavaara, T. and Niinistö, L. Chem. Mater. Vol.13 (2001) pp 4701-4707.

### DISCLOSURE OF THE INVENTION

The object of this invention is to provide an improved method for producing cathode diffusion barrier layer, and with that to provide a solid oxide fuel cell that has higher efficiency and longevity than known from the state of art.

It comprises depositing a pure ceria or aliovalently doped ceria layer, by atomic layer deposition, on the electrolyte layer of the sintered half cell. The surface of a electrolyte onto which film is to be deposited is exposed to a dose of vapor from one or more lanthanide first precursors. Then any excess unreacted vapor from that precursor is removed (pumped or purged away). Next, a vapor dose of the second precursor is brought to the surface and allowed to react. A second purge completes the ALD cycle.

This cycle of steps is repeated to build up thicker films. Different lanthanides in consecutive cycles will be used to build mixed oxides. This ceria layer forms a cathode diffusion barrier layer on top of which a cobaltite based cathode layer is applied by screenprinting, and the cathode diffusion barrier layer and cathode layer are heated together to form a improved solid oxide fuel cell. The heating temperature is between 1000-1200° C., preferably between 1000 and 1100° C.

The first precursors are lanthanide diketonates with general formula Ln(thd)ₙ, where thd is 2,2,6,6-tetramethylheptane-3,5-dionate, or any other volatile lanthanide compound that is thermally stable enough for meeting the requirement of self-limiting growth. The pulsing ratio for deposition of first precursors Ce(thd)₄ and Y(thd)₃ or Gd(thd)₃ is from 30:1 to 5:1, preferably 10:1. The second precursor is ozone or water.

The electrolyte layer is yttrium stabilized zirconia or scandium stabilized zirconia, and ceria layer is preferably Y or Gd doped ceria layer.

The cobaltite based cathode layer is preferably LSC (LaₓSr₍₁₋ₓ₎CoO₃) or LSCF (LaₓSr₍₁₋ₓ₎Co_{y}Fe_{(1-y)}O₃) layer.

The object of current invention is also a solid oxide fuel cell, comprising cathode diffusion barrier layer, produced by method described above.

### BRIEF DESCRIPTION OF DRAWINGS

FIG. 1. Fuel cell scheme. 1—cathode, 2—cathode diffusion barrier layer, 3—electrolyte, 4—anode active layer, 5—anode support layer.

FIG. 2. Fuel cell. 1—cathode, 2—cathode diffusion barrier layer, 3—electrolyte, 4—anode active layer, 5 anode support layer.

FIG. 3. Fuel cell in more detail. 1—cathode, 2—cathode diffusion barrier layer, 3—electrolyte.

FIG. 4. Growth rates of a) CeO₂ b) Gd₂O₃ and c) Y₂O₃ with different metal precursor pulse lengths of 0.5-2.0 s. The deposition temperature was 250° C.

FIG. 5. XRD patterns of 200 nm thick CeO₂, CeO₂:Gd and CeO₂:Y films on Si(100).

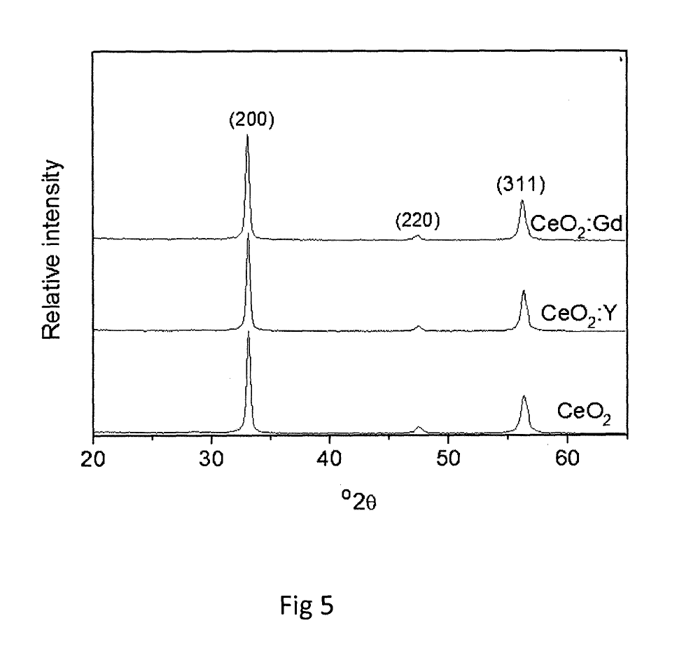

### DETAILED DESCRIPTION OF THE PREFERRED EMBODIMENTS

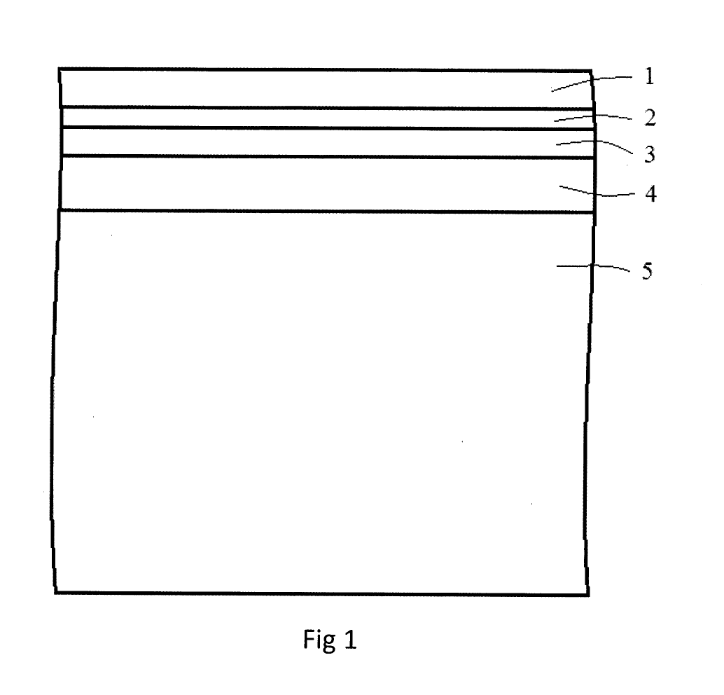

The fuel cell is produced by depositing a aliovalently doped ceria layer, preferably Y or Gd doped ceria layer, by ALD, on the yttrium stabilized zirconia electrolyte layer of the sintered half cell, on top of that is screen printed a cobaltite based cathode layer, preferably lanthanum strontium cobaltite (LaₓSr₍₁₋ₓ₎CoO₃) (LSC) or lanthanum strontium cobaltite ferrite (LaₓSr₍₁₋ₓ₎Co_{y}Fe_{(1-y)}O₃) (LSCF) layer, and the so covered cell is heated between 1000° C. and 1200° C., preferably between 1000° C. and 1100° C. The scheme of the cell is on FIG. 1.

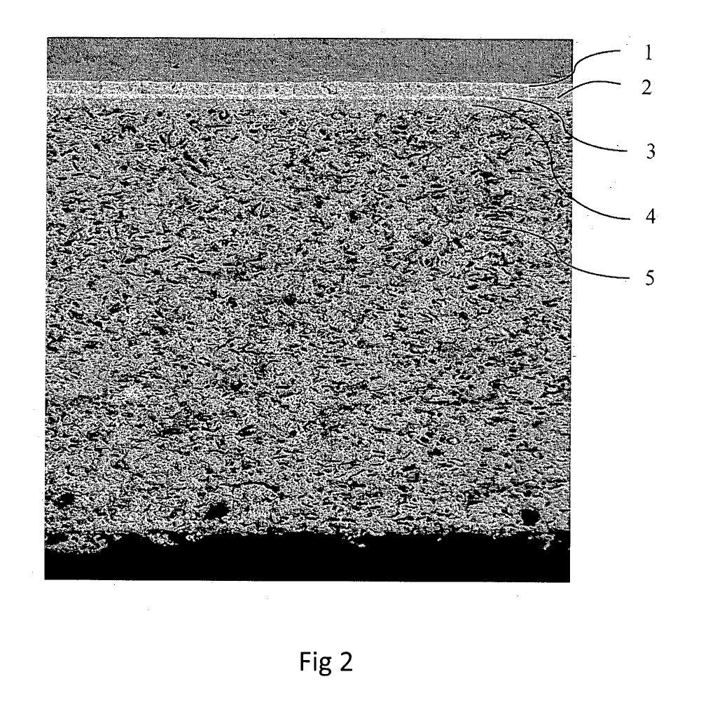

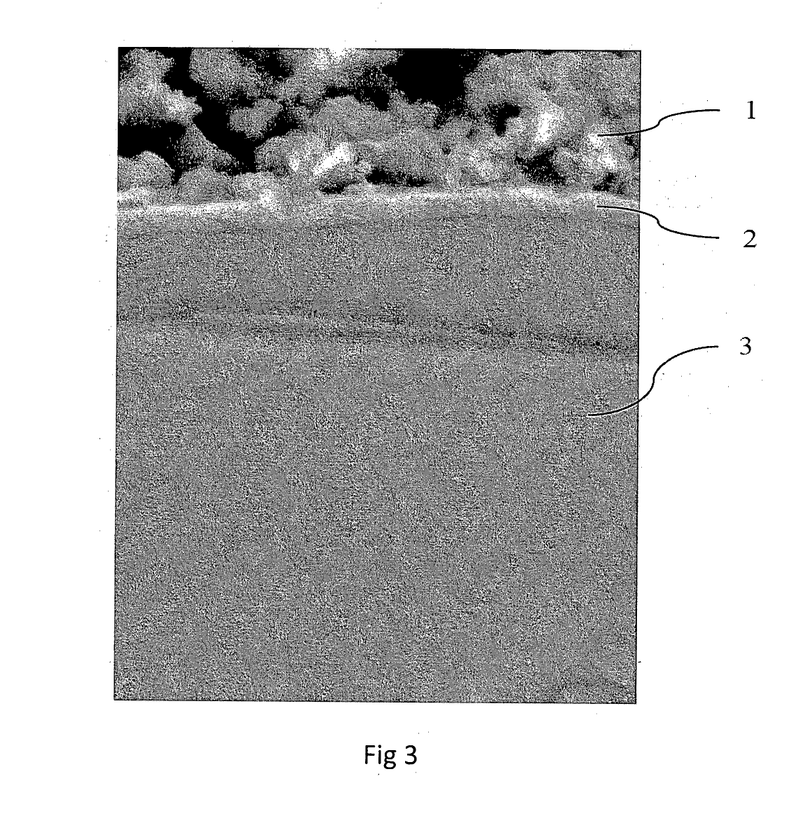

The heating of the raw ALD layer together with the cathode layer produces advantageous contact between cathode diffusion barrier layer and electrolyte layer, and cathode diffusion barrier layer and cathode layer. This provides almost continuous cathode diffusion barrier layer with lower electrical resistivity and better diffusion resistance than state of art. SEM cross-sections of the cell are on FIGS. 2 and 3.

The ALD cathode diffusion barrier layer has multiple advantages over state of art. Compared to screen printed layer it is denser, forming better barrier for cation diffusion. It is produced at lower temperature minimizing interdiffusion of barrier layer material and electrolyte material, lowering electrical resistance of the fuel cell. It also excludes one heating round from the production cycle, increasing the productivity and lowering cost.

Compared to physical vapor deposition (sputtering), ALD cathode diffusion barrier layer is denser, much more conformal, avoids columnar structure, and with that forms a better barrier for cation diffusion. ALD method has also advantages over sputtering for industrial scaling up, as the fuel cells can be packed close together in the reactor chamber.

### EXAMPLES

### 1. CeO₂, CeO₂:Gd and CeO₂:Y Cathode Diffusion Diffusion Barrier Layers for Solid Oxide Fuel Cells by Atomic Layer Deposition

Diffusion barrier layers CeO₂, CeO₂:Gd and CeO₂:Y were deposited by atomic layer deposition (ALD) on solid oxide fuel cell (SOFC) button cells to prevent the diffusion of cations from the cathode to the electrolyte. First, the growth rates of binary oxides CeO₂, Gd₂O₃ and Y₂O₃ were determined on Si(100) wafers and yttria stabilized zirconia (YSZ). Doped films were then deposited on Si(100) with different Ce:Gd and Ce:Y precursor pulse ratios to find the right ratio for the dopant content. The actual films were deposited on SOFC half cells that consisted of NiO/YSZ anode and YSZ electrolyte.

All films were deposited in a flow-type hot-wall ALD reactor (ASM Microchemistry F-120). Pressure in the reactor was 5-10 mbar. Ce(thd)4, Gd(thd)3 and Y(thd)3 (thd=2,2,6,6-tetramethyl-3,5-heptanedione) (VolatecOy) were used as metal precursors and ozone (100 g/m3) produced from oxygen (AGA, 99.999%) with ozone generator (Wedeco OZOMATIC 4 HC) was used as an oxygen source. Nitrogen (Domnick Hunter N2 generator, >99.999%) was used as carrier and purging gas.

Film thicknesses were determined from reflectance spectra. The spectra were measured at wavelengths between 370 and 1100 nm in Hitachi U-2000 spectrophotometer. The thickness of CeO₂ on YSZ was determined from k values of the elements measured with energy dispersive X-ray analysis (EDX). The dopant levels of the doped films were also determined by EDX. Crystallinity of the deposited films was determined by X-ray diffraction (XRD) with Cu Ka radiation in PanalyticalX'Pert PRO MPD diffractometer.

The binary oxides CeO₂, Gd₂O₃ and Y₂O₃ deposited by ALD have been thoroughly studied before. Reported growth rates are 0.32 Å/cycle for CeO₂, 0.30 Å/cycle for Gd₂O₃ and 0.22-0.23 Å/cycle for Y₂O₃ at 250° C. In this work the growth rates were 0.31 Å/cycle for CeO₂, 0.30 Å/cycle for Gd₂O₃ and 0.25 Å/cycle for Y₂O₃ at 250° C.

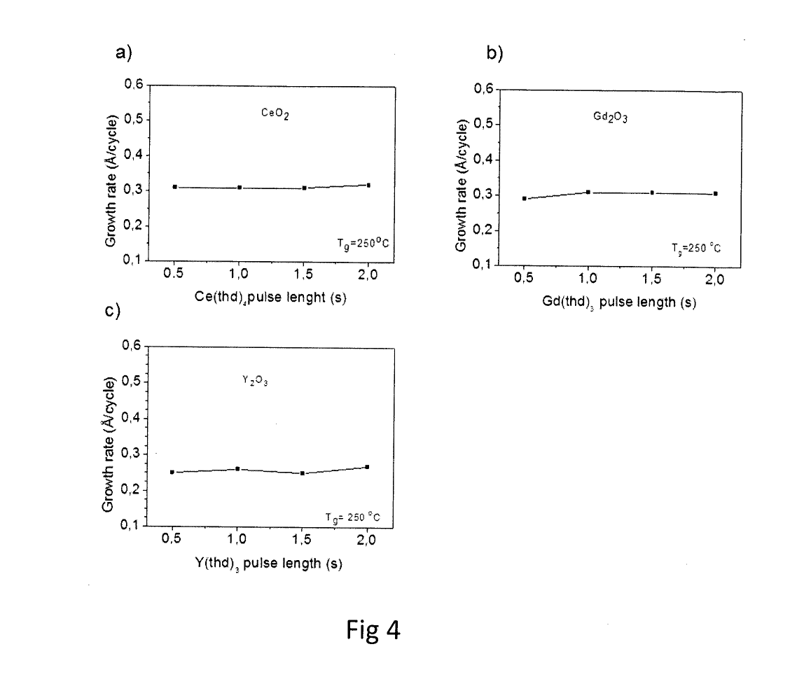

The growth rate of CeO₂ on YSZ was only slightly lower than on Si(100). In all cases, ALD type self-limiting growth mode was confirmed (FIG. 4).

Doped films were deposited on Si and the right Gd:Ce and Y:Ce precursor pulsing ratios in order to obtain 10 cation-% dopant level were determined. The studied pulsing ratios and dopant contents measured by EDX are presented in Tables 1 and 2.

TABLE 1
Gadolinium content of CeO₂:Gd films deposited with
different pulsing ratios.

| Gd:Ce pulse ratio | Gd (cation-%) |
|---|---|
| 1:2 | 38 |
| 1:10 | 12 |
| 1:20 | 8 |

TABLE 2
Yttrium content of CeO₂:Y films deposited with
different pulsing ratios.

| Y:Ce pulse ratio | Y (cation-%) |
|---|---|
| 1:1 | 57 |
| 1:2 | 41 |
| 1:10 | 10 |

### 2. Cell Manufacturing

First a half-cell is manufactured. The half-cell is manufactured by tape casting the anode support layer composed of YSZ and NiO (5), screen printing on top of this anode active layer composed of YSZ and NiO (4), screen printing on top of this electrolyte layer composed of YSZ (3), and sintering this multilayer green half-cell at 1400° C.

The complete fuel cell is produced by depositing a pure ceria or aliovalently doped ceria layer, preferably Y or Gd doped ceria layer, by ALD, on the yttrium stabilized zirconia electrolyte layer of the sintered half cell, on top of that is screen printed a cobaltite based cathode layer, preferably LSC or LSCF layer, and the so covered cell is heated between 1000° C. and 1200° C., preferably between 1000° C. and 1100° C., so that temperature stays over 1000° C. for at least one hour. Based on the above ALD results, pulsing ratio of 1:10 was chosen for the deposition of CeO₂:Gd and CeO₂:Y films on SOFC button cells. The deposition temperature was 250° C. Ce(thd)₄ was kept at 170° C., Gd(thd)₃ at 137° C., and Y(thd)₃ at 127° C. Pulse lengths were 0.5 s for Gd(thd)₃ and Ce(thd)₄, and 1.0 s for Y(thd)₃. Purge was 1.0 s after Gd(thd)₃ and Ce(thd)₄ pulses, and 1.5 s after Y(thd)₃ pulses. Ozone pulse was always 1.0 s and purge after ozone 1.5 s. In order to deposit 100 nm thick CeO₂ films, 3334 cycles were applied. For 200 nm thick films 7800 cycles were applied. For doped films, 10 cycles of CeO₂ was deposited first and then one cycle of Gd₂O₃ or Y₂O₃. For 100 nm thick films this sequence was repeated 337 times and for 200 nm thick films 674 times.

The XRD patterns of 200 nm thick CeO₂, CeO₂:Gd and CeO₂:Y films on Si(100) are shown in FIG. 2. The phase is cubic CeO₂ (PDF card 34-0394) and the most intensive reflection is (200).

1. A method of producing solid oxide fuel cell (SOFC) cathode diffusion barrier layer comprising the subsequent steps of:
a) depositing a pure ceria or aliovalently doped ceria layer, by atomic layer deposition, on an electrolyte layer composed of aliovalently stabilized zirconia, of a sintered half cell, wherein the surface of the electrolyte onto which film is to be deposited is exposed to a dose of vapor from one or more lanthanide first precursors, and any excess unreacted vapor from that precursor is removed, and a vapor dose of a second precursor is brought to the surface and allowed to react, and this cycle of steps is repeated to build up thicker films;
b) screenprinting on top of said layers cobaltite based cathode layer; and
c) heating the cathode diffusion barrier layer and cathode layer together.

2. The method of claim 1, wherein the first precursors are lanthanide diketonates with general formula Ln(thd)ₙ, wherein thd is 2,2,6,6-tetramethylheptane-3,5-dionate, or any other volatile lanthanide compound that is thermally stable enough for meeting the requirement of self-limiting growth, and the second precursor is ozone or water.

3. The method of claim 1, wherein the electrolyte layer is yttrium stabilized zirconia.

4. The method of claim 1, wherein the electrolyte layer is scandium stabilized zirconia.

5. The method of claim 1, wherein said ceria layer is preferably Y or Gd doped ceria layer.

6. The method of claim 5, wherein tie pulsing ratio for deposition of first precursors Ce(thd)₄ and Y(thd)₃. or Gd(thd)₃ is from 30:1 to 5:1.

7. The method of claim 1, wherein said cobaltite based cathode layer is preferably LSC (LaₓSr₍₁₋ₓ₎CoO₃) or LSCF (LaₓSr₍₁₋ₓ₎Co_{y}Fe_{(1-y)}O₃) layer.

8. The method of claim 1, wherein heating temperature in step c) is between 1000-1200° C.

9. The method of claim 1, wherein different lanthanides in consecutive cycles of step a) are used to build mixed oxides.

10. A solid oxide fuel cell (SOFC), comprising cathode diffusion barrier layer, produced by the method of claim 1.

11. The method of claim 6, wherein the pulsing ratio for deposition of first precursors Ce(thd)₄ and Y(thd)₃. or Gd(thd)₃ is 10:1.

12. The method of claim 8, wherein the heating temperature is between 1000-1100° C.
